(19) United States
(12) Patent Application Publication
(10) Pub. No.: US 2023/0144651 A1
(43) Pub. Date: May 11, 2023

(54) HEAT DISSIPATION SHEET USING GRAPHENE-GRAPHITE COMPOSITE AND METHOD OF MANUFACTURING THE SAME

(71) Applicant: TERASYS. CO., LTD, Uiwang-si (KR)

(72) Inventors: Jong Un PARK, Yongin-si (KR); Chi Young CHOI, Uiwang-si (KR)

(73) Assignee: TERASYS. CO., LTD, Uiwang-si (KR)

(21) Appl. No.: 17/982,974

(22) Filed: Nov. 8, 2022

(30) Foreign Application Priority Data
Nov. 10, 2021 (KR) 10-2021-0154079

(51) Int. Cl. F28F 21/02; B32B 3/26; B32B 9/00; B32B 7/12; B32B 37/12; B32B 9/04; B32B 27/36; B32B 27/28

(52) U.S. Cl. CPC F28F 21/02; B32B 3/266; B32B 9/007; B32B 7/12; B32B 37/12; B32B 9/045; B32B 27/36; B32B 27/281; F28F 2275/025; F28F 2230/00; B32B 2313/04; B32B 2307/748; B32B 2307/30

(57) ABSTRACT

An heat dissipation sheet with excellent thermal conductivity, which is capable of reducing manufacturing cost, is disclosed. The heat dissipation sheet of the present invention comprises a graphite layer, a first graphene layer and a second graphene layer. The first graphene layer is attached to a first surface of the graphite layer through a first adhesive layer. The second graphene layer is attached to a second surface of the graphite layer through a second adhesive layer.

### CROSS REFERENCE TO RELATED APPLICATION

This application claims priority from and the benefit of Korean Patent Applications No. 10-2021-0154079, filed on Nov. 10, 2021, which is hereby incorporated by reference for all purposes as if fully set forth herein.

### BACKGROUND OF THE INVENTION

### Field of the Invention

The present invention relates to a heat dissipation sheet using graphene-graphite composite, more specifically to a heat dissipation sheet with a composite layer structure of graphene and graphite, and a method of manufacturing the heat dissipation sheet.

### Discussion of the Background

Materials composed of carbon atoms include fullerene, carbon nanotube, graphene, graphite, and the like. Among them, graphene has a structure in which carbon atoms are composed of one layer of atoms on a two-dimensional plane.

In particular, graphene has very stable and excellent electrical, mechanical, and chemical properties, it moves electrons much faster than silicon and can flow a much larger current than copper and as an excellent conductive material.

In addition, graphene has excellent thermal conductivity, so it can be applied to heat dissipating materials that emit heat. For example, a heat dissipation sheet can by manufactured by using graphene and is attached to a heat generating component to emit heat, and related prior arts are known.

However, graphene requires high production cost, long mass production time, and huge equipment cost. Therefore, it is necessary to study a heat dissipation sheet with excellent heat dissipation performance while compensating for such shortcomings of graphene.

### SUMMARY OF THE INVENTION

Therefore, the present invention provides an economical and excellent heat dissipation sheet by composing a heat dissipation sheet to have a composite layer structure of graphene and graphite so that heat dissipation performance can be appropriately exhibited even with a small amount of graphene.

In addition, the present invention provide a method of manufacturing a heat dissipation sheet having a layer structure in which graphene and graphite are combined.

The heat dissipation sheet of the present invention comprises a graphite layer, a first graphene layer and a second graphene layer. The first graphene layer is attached to a first surface of the graphite layer through a first adhesive layer. The second graphene layer is attached to a second surface of the graphite layer through a second adhesive layer.

The first adhesive layer and the second adhesive layer may be an adhesive sheet with is through holes.

The heat dissipation sheet may further comprises two protective layers attached to the first and second graphene layers two third adhesive layers, respectively.

The graphite layer may be disposed within an area of the first and second graphene layers such that a circumference of the graphite layer is disposed inside of a circumference of the first and second graphene layers, and the heat dissipation sheet may further comprise a sealing layer having a thickness corresponding to a thickness of the graphite layer, and surrounding the graphite layer.

A method of manufacturing a heat dissipation layer according to an exemplary embodiment of the present invention, comprises preparing two laminates with graphene layer and a protective layer, respectively, forming an adhesive layer on the graphene layer of the two laminate, and forming a graphite layer between the adhesive layers of the two laminates.

For example, the adhesive layer may be formed by attaching an adhesive sheet with a release film, on which the adhesive layer is formed, to the graphene layer, and removing the release film.

For example, the adhesive sheet may have through holes.

For example, the graphite layer may have a smaller area than an area of the adjacent graphene layer, and may be formed within the area of the graphene layer, such that a space is formed around the graphite layer where the outer edges of the graphene layers face each other, and the method may further comprise forming a sealing layer of which thickness is substantially equal to a thickness of the graphite layer in the space around the graphite layer.

For example, wherein the sealing layer may comprise graphene.

The heat dissipation sheet according to an embodiment of the present invention has an excellent heat dissipation effect by forming a graphite layer between the graphene layers, and the cost required for manufacturing the heat dissipation sheet can be reduced.

In addition, since the adhesive layer for laminating the graphene layer and the graphite layer is made of an adhesive sheet, it is possible to laminate the graphene layer and the graphite layer in a simple way. Further, since the adhesive layer has through holes for heat transferring between the graphene layer and the graphite layer, a higher heat dissipation effect can be obtained.

On the other hand, by making the area of the graphite layer smaller than the area of the graphene layer to form a graphene layer around the graphite layer of which the raw material is in powder form, is sealed, so that the graphite layer can be stably maintained. Further, the added graphene layer around the graphite layer can increase the heat dissipation effect.

Other effects of the present invention will be clearly grasped and understood by experts or researchers in the art through the specific details described below, or during the course of carrying out the present invention.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention

FIG. 1 is a cross-sectional view showing a heat dissipation sheet according to a first embodiment of the present invention.

FIG. 2A is a cross-sectional view showing a heat dissipation sheet according to a second embodiment of the present invention.

FIG. 2B is a perspective view showing first or second adhesive layer in FIG. 2A.

FIG. 3 is a cross-sectional view showing a heat dissipation sheet according to a third embodiment of the present invention.

FIG. 4 is a flowchart showing a method of manufacturing a heat dissipation sheet according to an embodiment of the present invention.

FIGS. 5A to 5F are process charts showing a method of manufacturing a heat dissipation sheet according to the embodiment shown in FIG. 1.

FIGS. 6A to 6G are process charts showing a method of manufacturing a heat dissipation sheet according to the embodiment shown in FIG. 3.

### DETAILED DESCRIPTION OF THE ILLUSTRATED EMBODIMENTS

The accompanying drawings show an applied embodiment of the present invention, and the technical spirit of the present invention should not be construed as being limited through the accompanying drawings. If it can be interpreted that some or all of the accompanying drawings are not necessary for the shape, and order required for the practice of the invention from the point of view of an expert in this technical field, this does not limit the invention described in the claims.

The features and effects of the present invention described above will become more apparent through the following detailed description in relation to the accompanying drawings, and accordingly, those of ordinary skill in the art to which the present invention pertains can easily implement the technical idea of the present invention. The present invention can have various changes and can have various forms, specific embodiments are illustrated in the drawings and described in detail in the text. However, this is not intended to limit the present invention to a specific disclosed form, it should be understood to include all modifications, equivalents and substitutes included in the spirit and scope of the present invention. The terms used in the present application are only used to describe specific embodiments, and are not intended to limit the present invention.

Hereinafter, a heat dissipation sheet and a method of manufacturing the heat dissipation sheet according to an embodiment of the present invention will be described in detail with reference to the drawings. In the present specification, the same and similar reference numerals are assigned to the same and similar components in different embodiments, and repeated explanation will be omitted.

A heat dissipation sheet 100 according to an embodiment of the present invention includes a graphite layer 1, a first graphene layer 2, and a second graphene layer 3. The graphite layer 1 is located at the center of the stacking, and heat dissipation sheet 100 is formed by stacking a first graphene layer 2 on one side of the graphite layer 1 through a first adhesive layer 4, and a second graphene layer 3 on the other side of the graphite layer 1 through a second adhesive layer 5. Accordingly, the graphite layer 1 is positioned between a pair of graphene layers 2 and 3.

By compounding graphene with graphite, which is excellent in economy and heat dissipation performance, it is possible to reduce the amount of graphene used in the heat dissipation sheet, obtain high heat dissipation performance, and improve economic efficiency.

Hereinafter, the configuration of each part will be described in detail with reference to the drawings.

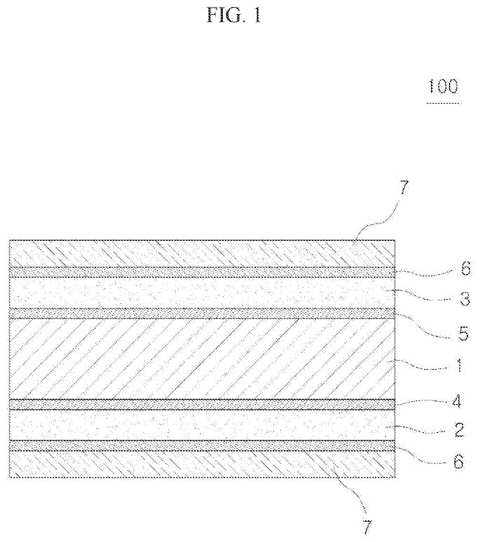

FIG. 1 is a cross-sectional view showing a heat dissipation sheet according to a first embodiment of the present invention.

The graphite layer 1 is formed by molding graphite in powder form into a thin layer. Graphite is a widely known heat dissipation material, and its heat dissipation characteristics are about 1000˜2000 W/mk. Graphite has lower heat dissipation properties than graphene, but is a highly economical heat dissipation material.

Graphite is generally divided into two types: natural graphite and artificial graphite. Since natural graphite has various impurities, its heat dissipation properties are inferior to that of artificial graphite.

Artificial graphite is mostly made by burning polyimide film (PI) at a high temperature, and concentrating ash thereof. The general heat dissipation characteristics of artificial graphite are about 1200˜1800 W/mk.

The graphene layer consists of a thin layer of graphene. Graphene has been in the spotlight as a new material that has the potential to be used in various fields since its discovery in the year of 2004.

Graphene is 100 to 300 times stronger than steel, and the thermal conductivity of graphene at room temperature is 5300 W/mk, which is superior to diamond. It also has excellent electrical conductivity, flexibility, and transparency.

On the other hand, high production cost, time required for mass production, huge equipment cost, etc. are required, so an economical value has not been secured yet.

In general, graphene is produced by dry and wet methods in general. According to the dry method, a gas layer containing carbon atoms is decomposed at a high temperature by using a chemical vapor deposition (CVD) technique to generate the graphene. While it has the advantage of growing a homogeneous and uniform graphene layer, it has a disadvantage in that the production rate is slow.

On the other hand, according to the wet method, carbon molecules are decomposed in a solution to generate the graphene. Although it has the advantage of high production speed, it is difficult to obtain high-purity graphene and it is difficult to make a homogeneous graphene layer.

In this embodiment, graphene can be employed in any graphene produced by any of the wet method and dry method described above, and the first graphene layer 2 and the second graphene layer 3 are attached to each side of the graphite layer 1, respectively to form the heat dissipation sheet 100 with graphene-graphite composite.

The first adhesive layer 4 and the second adhesive layer 5 attach the first graphene layer 2 and the second graphene layer 3 to the lower and upper surfaces of the graphite layer 1, respectively. Through the first and second adhesive layers 4 and 5, the first graphene layers 2, the graphite layer 1 and the second graphene layer 3 are integrated to function as one heat dissipation sheet 100.

The first adhesive layer 4 and the second adhesive layer 5 may be formed of an adhesive sheet. The adhesive sheet has the form of a thin plate. Accordingly, since there is no liquid-like flow, it is possible to firmly attach the first and second graphene layers 2 and 3 to the graphite layer 1 without leaking when each layer is stacked.

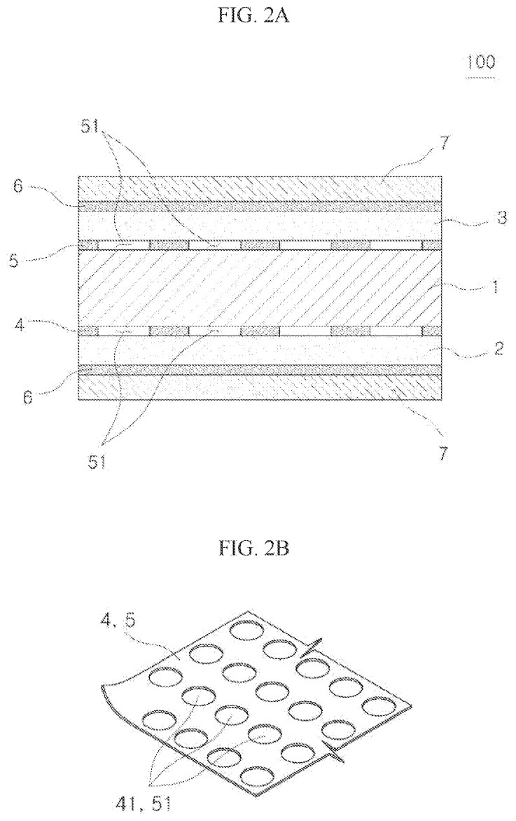

Meanwhile, as shown in FIGS. 2A and 2B, the first and second adhesive layers 4 and 5 may have through holes 41 and 51, respectively. The through holes 41 and 51 may be formed at regular intervals. The through holes 41 and 51 increase the heat dissipation effect. By forming the through-holes 41 and 51, heat transfer between the graphite layer 1 and the first and second graphene layers 2 and 3 is promoted, and heat is rapidly transferred to the vertical direction, thereby further enhancing the heat dissipation effect.

In addition, the protective layer 7 may be attached to the outside of the first graphene layer 2 and the second graphene layer 3 by through the third adhesive layer 6.

The protective layer 7 serves to protect the first graphene layer 2 and the second graphene layer 3 exposed to the outside. The third adhesive layer 6 allows the protective layer 7 to be stably stacked on the outside of the first graphene layer 2 and the second graphene layer 3.

The third adhesive layer 6 is formed on one surface of the protective layer 7, and a liner film (or release film) may be attached to the other surface of the protective layer 7. The protective layer 7 is attached to the first graphene layer 2 and the second graphene layer 3 through the third adhesive layer 6, and the liner film is removed, so that the protective layer 7 can be formed easily.

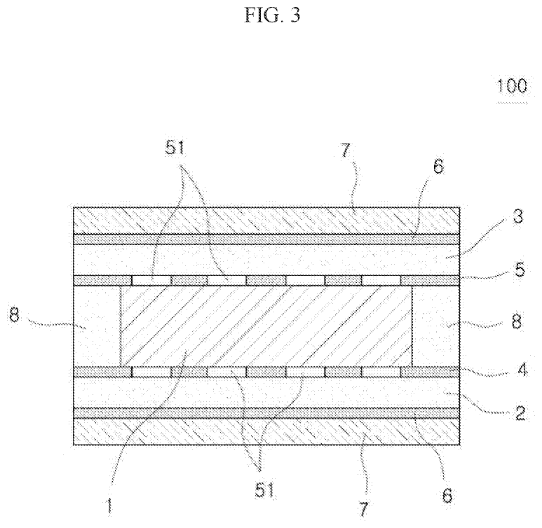

Meanwhile, as described above, the graphite layer 1 is made of graphite powder. Therefore, there is a possibility that the layer structure may be deformed by an external impact. In order to prevent this, a configuration for sealing the outside of the graphite layer 1 may be considered as shown in FIG. 3.

FIG. 3 is a view showing a heat dissipation sheet 100 according to a third embodiment of the present invention. Referring to FIG. 3, the area of the graphite layer 1 is smaller than the area of the first graphene layer 2 and the second graphene layer 3. In addition, the graphite layer 1 is disposed within the area of the first graphene layer 2 and the second graphene layer 3 such that the circumference of the graphite layer 1 is disposed inside of the circumference of the first graphene layer 2 and the second graphene layer 3.

In addition to this, a sealing layer 8 having the same thickness as the graphite layer 1 and surrounding the graphite layer 1 is formed outside the graphite layer 1.

The sealing layer 8 may be made of graphene. Graphene has carbon atoms arranged with a honeycomb-shape with a two-dimensional structure. Graphene is not in powder form, and adheres to an adhesive sheet and maintains its structure as it is. Accordingly, it is possible to reduce the possibility that the structure of the graphite layer 1 is deformed.

In addition, if graphene is adopted as a material for sealing the graphite layer 1, the heat dissipation effect can be maximized because the heat dissipation area can be increased by adding graphene to a sealing work space.

On the other hand, the thickness of one graphene layer is about 0.2 to 0.3 nm, which is about 1/10000 times smaller than that of a general graphite layer 1 of 10 to 30 μm. Therefore, with graphene having a thickness corresponding to the thickness of the graphite layer 1, both sides of the graphene are attached to the first adhesive layer 4 and the second adhesive layer 5 respectively, to form to sealing layer 8, and the graphite layer 1 is enclosed and sealed.

Hereinafter, a method for manufacturing the heat dissipation sheet according to an embodiment of the present invention will be described in detail with reference to the drawings.

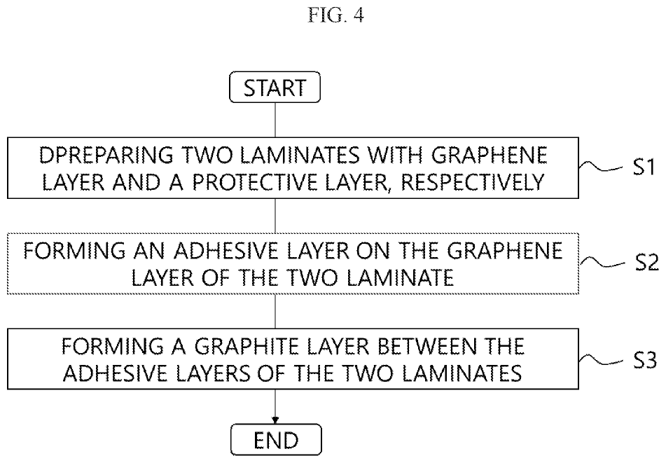

FIG. 4 is a flowchart showing a method for manufacturing a heat dissipation sheet according to an embodiment of the present invention.

Referring to FIG. 4, a method for manufacturing a heat dissipation sheet according to an embodiment of the present invention, includes a first step of preparing two laminates with graphene layer and a protective layer, respectively (step S1), a second step of forming an adhesive layer on the graphene layer of the two laminate in the previous step (step S2), and a third step of forming a graphite layer between the adhesive layers of the two laminates prepared in the previous step (step S3).

Hereinafter, a method of manufacturing the heat dissipation sheet of the first embodiment and the third embodiment will be described with reference to the drawings. In the case of the second embodiment, only the adhesive layer is different from that of the first embodiment, and the method of manufacturing the heat dissipation sheet of the first embodiment can be applied to the method of manufacturing the heat dissipation sheet of the second embodiment.

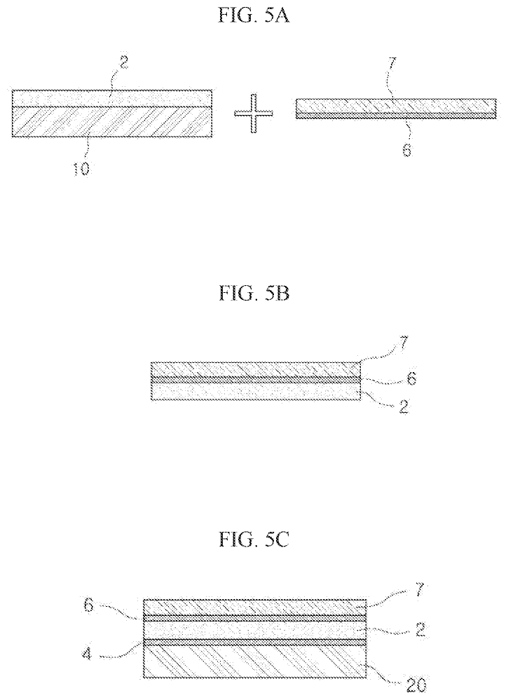

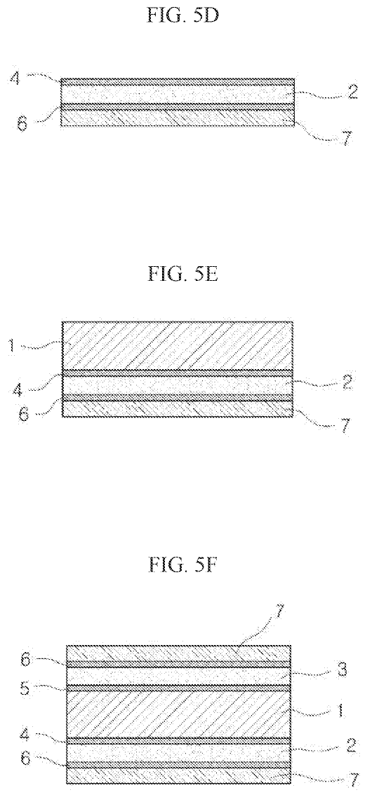

FIGS. 5A to 5F are process charts showing a method of manufacturing a heat dissipation sheet according to the embodiment shown in FIG. 1.

The first step (S1 in FIG. 4) of preparing two laminates in which the graphene layers 2 and 3 and the protective layer 7 are stacked may be specifically performed as follows.

A PET film or a PI film, on which the graphene layer will be seated, is prepared. The film surface in contact with the graphene surface may have a certain adhesive component, and for this purpose, the PET film or the PI film may be formed of a liner film having an adhesive layer on one side (see the left side of FIG. 5A).

Meanwhile, a step of growing graphene on the catalytic metal material 10 (eg, copper foil or metal foil) is performed for the production of graphene. When the CVD (chemical vapor deposition) technique is used, carbon is adsorbed to the metal surface and crystallized to produce graphene (see the right side of FIG. 5A).

Then, the catalytic metal material 10 to which the graphene is adsorbed is removed. For the removal of the catalytic metal material 10, for example, an etching solution reacting with the catalytic metal material 10 may be used. Through this process, it is possible to obtain pure graphene without the catalytic metal material 10.

Next, the graphene produced as above is attached to the film surface with the adhesive component to form a laminate in which the graphene layer and the protective layer 7 are laminated with the adhesive layer interposed therebetween (see FIG. 5B). This process may be performed through a lamination process. Two laminates are prepared.

In the second step, an adhesive layer is formed on an opposite side of the graphene layer, which is opposite to a side on which the protective layer is laminated in the laminate formed in the first step.

The adhesive layer may be formed by applying an adhesive thinly, but the adhesive layer may be formed by using an adhesive sheet on which the adhesive layer is formed.

Specifically, an adhesive sheet with an adhesive layer 4 and a release paper 20 attached to the adhesive layer 4 is attached to one side of the graphene layer 2 (see FIG. 5C), and then the release paper 20 is removed to remove the adhesive sheet (see FIG. 5D). In this case, as shown in FIG. 2, the adhesive sheet may have through holes 41 and 51 formed therein.

In addition, as described above, when the adhesive layer is formed using the adhesive sheet to which the release paper is attached, it is possible to form the adhesive layer having the through hole in a simple manner.

In the third step, a pair of laminates having an adhesive layer formed on one side of the graphene layer formed in the second step are prepared, and the first adhesive layer 4 and the second adhesive layer 5 are made to face each other so that the graphite is laminated between the opposite adhesive layers. Such a process can be performed as follows.

First, graphite is added to a predetermined thickness on the adhesive layer of the laminate with the adhesive layer 4, the graphene layer 2, the third adhesive layer 6, and the protective layer 7 stacked in the second step (see FIG. 5E). In this case, the graphite may be formed in a plate shape.

Next, another laminate that has undergone the second step as described above is laminated on the graphite layer 1 (see FIG. 5F). At this time, the adhesive layer 5 is brought into contact with the graphite layer 1.

Next, graphite and graphene are laminated. Lamination of graphite and graphene may be performed using a lamination process. Accordingly, a so-called sandwich structure in which graphite is laminated between graphene is formed.

As described above, a graphene-graphite composite in which a graphite layer is formed between a pair of graphene layers may be manufactured.

Meanwhile, in order to improve the physical properties and heat dissipation properties of graphite, it is also possible to manufacture the heat dissipation sheet in the following manner.

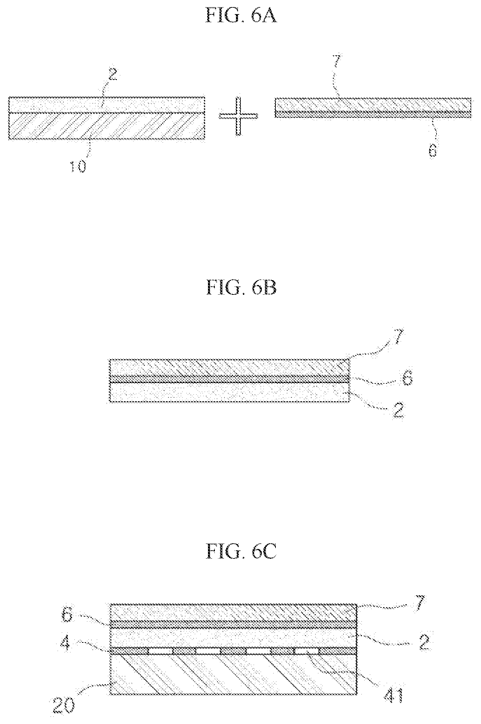

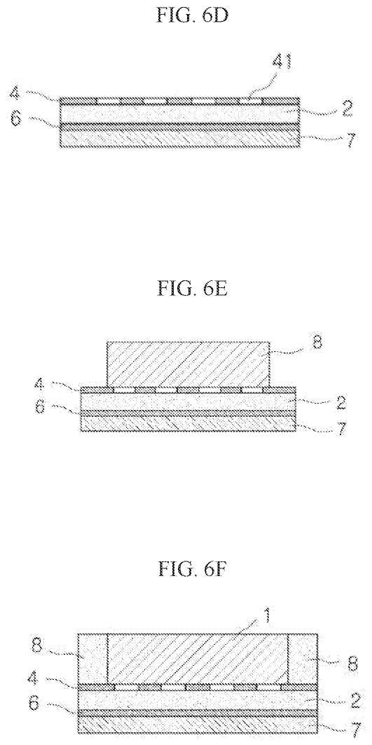

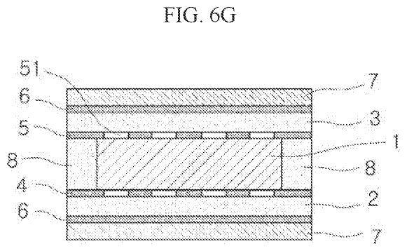

FIGS. 6A to 6G are process charts showing a method of manufacturing a heat dissipation sheet according to the embodiment shown in FIG. 3.

Referring to the drawings, in the present manufacturing method, the first step (refer to FIGS. 6A and 6B) is the same as the above-described manufacturing method, and thus repetitive descriptions are omitted. In addition, in the second step, the adhesive layer in which the through holes 41 and 51 are formed as described above was adopted (see FIGS. 6C and 6D).

Meanwhile, in the third step, the graphite layer 1 having a smaller area than the area of the adjacent graphene layer, is formed within the area of the graphene layer so that a space in which the graphene layers 2 and 3 face each other is formed around the graphite layer 1 (see FIG. 6E).

On the other hand, the method further comprises the step of additionally forming a sealing layer 8 of which thickness is substantially equal to the thickness of the graphite layer 1 around the graphite layer 1 (see FIG. 6F) to complete the lamination step of the third step (see FIG. 6G).

In this case, the sealing layer 8 may be made of graphene. The sealing layer 8 may be formed by graphene having a plate shape with a hole at a center thereof, through which the graphite layer 1 passes. The sealing layer 8 may be formed in such a way that the graphite layer 1 is penetrated through the graphene in which the holes are formed so that the graphene is stacked around the graphite layer 1.

On the other hand, the sealing layer 8 may be formed by disposing the graphene pieces in the form of sealing the circumference of the graphite layer 1 by using a plurality of plate-shaped graphene pieces.

According to this method, it is possible to expect improvement of the physical properties and heat dissipation properties of graphite, and it is possible to manufacture a heat dissipation sheet having better thermal conductivity.

Meanwhile, each step is not necessarily performed sequentially, and some steps may be performed simultaneously or independently.

As described above, in the heat dissipation sheet and the heat dissipation sheet manufacturing method according to the embodiment of the present invention, the configuration and method of the above-described embodiments are not limitedly applicable, but the embodiments are the examples of each embodiment so that various modifications can be made. All or a part may be selectively combined and configured.

It will be apparent to those skilled in the art that various modifications and variation may be made in the present invention without departing from the spirit or scope of the invention. Thus, it is intended that the present invention cover the modifications and variations of this invention provided they come within the scope of the appended claims and their equivalents.

What is claimed is:

1. A heat dissipation sheet comprising:
a graphite layer;
a first graphene layer attached to a first surface of the graphite layer through a first adhesive layer; and
a second graphene layer attached to a second surface of the graphite layer through a second adhesive layer.

2. The heat dissipation sheet of claim 1, wherein the first adhesive layer and the second adhesive layer are an adhesive sheet with through holes.

3. The heat dissipation sheet of claim 1, further comprising two protective layers attached to the first and second graphene layers two third adhesive layers, respectively.

4. The heat dissipation sheet of claim 1, wherein the graphite layer is disposed within an area of the first and second graphene layers such that a circumference of the graphite layer is disposed inside of a circumference of the first and second graphene layers, and further comprising:
a sealing layer having a thickness corresponding to a thickness of the graphite layer, and surrounding the graphite layer.

5. A method of manufacturing a heat dissipation layer, comprising:
preparing two laminates with graphene layer and a protective layer, respectively;
forming an adhesive layer on the graphene layer of the two laminate; and
forming a graphite layer between the adhesive layers of the two laminates.

6. The method of claim 5, wherein the adhesive layer is formed by:
attaching an adhesive sheet with a release film, on which the adhesive layer is formed, to the graphene layer; and
removing the release film.

7. The method of claim 6, wherein the adhesive sheet has through holes.

8. The method of claim 5, wherein the graphite layer has a smaller area than an area of the adjacent graphene layer, and is formed within the area of the graphene layer, such that a space is formed around the graphite layer where the outer edges of the graphene layers face each other, and further comprising:
forming a sealing layer of which thickness is substantially equal to a thickness of the graphite layer in the space around the graphite layer.

9. The method of claim 8, wherein the sealing layer comprises graphene.
